(19) United States
(12) Patent Application Publication
(10) Pub. No.: US 2025/0056833 A1
(43) Pub. Date: Feb. 13, 2025

(54) LATERALLY DIFFUSED METAL OXIDE SEMICONDUCTOR (LDMOS) TRANSISTOR INTEGRATION IN INTEGRATED CIRCUIT (IC) PLATFORM

(71) Applicant: QUALCOMM Incorporated, San Diego, CA (US)

(72) Inventor: Taehun KWON, San Diego, CA (US)

(21) Appl. No.: 18/366,441

(22) Filed: Aug. 7, 2023

(51) Int. Cl. H01L 29/78; H01L 29/66

(52) U.S. Cl. CPC H01L 29/7816; H01L 29/66681

(57) ABSTRACT

An integrated circuit (IC) device is described. The IC device includes a P-type substrate. The IC device also includes an N-type buried layer on the P-type substrate. The P-type substrate includes a non-uniformly doped layer in the N-type buried layer. The non-uniformly doped layer is proximate a first substrate region. The IC device also includes a first laterally diffused metal oxide semiconductor (LDMOS) transistor on the first substrate region.

### BACKGROUND

### Field

Aspects of the present disclosure relate to semiconductor devices and, more particularly, to a laterally diffused metal oxide semiconductor (LDMOS) transistor integration in an integrated circuit (IC) platform.

### Background

As integrated circuit (IC) technology advances, device geometries are reduced. Technological advances in IC materials and design have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down also increases the complexity of processing and manufacturing ICs. Moreover, realizing these advancements involves similar developments in IC processing and manufacturing of advanced logic complementary metal oxide semiconductor (CMOS) transistors.

A power management integrated circuit (PMIC) may use a CMOS transistor that is fabricated using a lower voltage IC process and implemented with an external inductor. By contrast, a type of CMOS transistor referred to as a laterally diffused metal oxide semiconductor (LDMOS) device may be fabricated using a higher voltage IC process. A PMIC having LDMOS transistors fabricated using the lower voltage IC process to enable formation of an LDMOS transistor that expands a voltage range of a PMIC from the lower voltage to the higher voltage without relying on an external inductor is desired.

### SUMMARY

An integrated circuit (IC) device is described. The IC device includes a P-type substrate. The IC device also includes an N-type buried layer on the P-type substrate. The P-type substrate includes a non-uniformly doped layer in the N-type buried layer. The non-uniformly doped layer is proximate a first substrate region. The IC device also includes a first laterally diffused metal oxide semiconductor (LDMOS) transistor on the first substrate region.

A method for transistor integration is described. The method includes depositing and patterning a first photoresist (PR) layer on a substrate to form a first window opening in the first PR layer exposing a first substrate region and second window openings in the first PR layer exposing a second substrate region. The method also includes implanting a first dopant in the first substrate region through the first window opening and the second substrate region through the second window openings in the first PR layer. The method further includes annealing the substrate to form an N-type buried layer in the first substrate region and a non-uniformly doped layer in the second substrate region. The method also includes depositing and patterning a second PR layer on the substrate to expose the second substrate region. The method further includes implanting a second dopant in the non-uniformly doped layer in the second substrate region through an opening in the second PR layer. The method also includes annealing the substrate to form an N-type buried layer in the second substrate region and including the non-uniformly doped layer.

This has outlined, broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for conducting the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer.

FIG. 2 illustrates a cross-sectional view of a die of FIG. 1.

FIG. 3 illustrates a cross-sectional view of a metal oxide semiconductor field effect transistor (MOSFET) device.

FIG. 4 is a cross-sectional view of an N-type, laterally diffused metal oxide semiconductor (LDMOS) transistor, according to various aspects of the present disclosure.

FIG. 5 is a cross-sectional view of an N-type, laterally diffused metal oxide semiconductor (LDMOS) transistor having a non-uniformly doped layer in an N-type buried layer, according to various aspects of the present disclosure.

FIGS. 6A-6D are schematic diagrams illustrating formation of the N-type, laterally diffused metal oxide semiconductor (LDMOS) transistor structures, according to various aspects of the present disclosure.

FIG. 7 is a process flow diagram illustrating a method of fabricating an N-type, laterally diffused metal oxide semiconductor (LDMOS) transistor having a non-uniformly doped layer in an N-type buried layer, according to various aspects of the present disclosure.

FIG. 8 is a block diagram showing an exemplary wireless communications system in which an aspect of the disclosure may be advantageously employed.

FIG. 9 is a block diagram illustrating a design workstation used for circuit, layout, and logic design of a transistor structure according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

As integrated circuit (IC) technology advances, device geometries are reduced. Technological advances in IC materials and design have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down also increases the complexity of processing and manufacturing ICs. Moreover, realizing these advancements involves similar developments in IC processing and manufacturing of advanced logic complementary metal oxide semiconductor (CMOS) transistors.

A power management integrated circuit (PMIC) may use a CMOS transistor that is fabricated using a lower voltage IC process and implemented with an external inductor. By contrast, a type of CMOS transistor is referred to as a laterally diffused metal oxide semiconductor (LDMOS) transistor. LDMOS transistors represent a type of an asymmetric power metal oxide semiconductor field effect transistor (MOSFET). LDMOS transistors are designed to achieve a low on-resistance and a high blocking voltage. These features may be supported by creating a diffused P-type channel region in a low-doped N-type drain region. A PMIC having LDMOS transistors fabricated using the lower voltage IC process to enable formation of an LDMOS transistor that expands a voltage range of a PMIC from the lower voltage to the higher voltage without reply on an external inductor is desired.

Various aspects of the present disclosure are directed to an N-type, laterally diffused metal oxide semiconductor (LDMOS) transistor having a non-uniformly doped layer in an N-type buried layer. The process flow for fabricating the LDMOS transistor having a lightly doped buried layer in a non-uniformly doped buried layer may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably unless such interchanging would tax credulity.

According to aspects of the present disclosure, a process of fabricating a higher voltage LDMOS transistor fabricated using a lower voltage IC process is described. The process includes depositing and patterning a first photoresist (PR) layer on a substrate to form a first window opening in the first PR layer exposing a first substrate region and second openings in the first PR layer exposing a second substrate region. The process also includes implanting a first dopant in the first substrate region through the first window opening and the second substrate region through the second window openings in the first PR layer. The process further includes annealing the substrate to form a doped N+ buried layer in the first substrate region and a lightly doped N+ buried layer in the second substrate region. The process also includes depositing and patterning a second PR layer on the substrate to expose the second substrate region. The process further includes implanting a second dopant in the lightly doped N+ buried layer in the second substrate region through an opening in the second PR layer. The process includes annealing the substrate to form a non-uniformly doped N− buried layer in the second substrate region and including the lightly doped N+ buried layer.

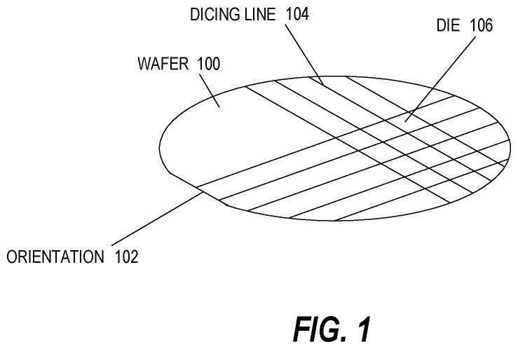

FIG. 1 illustrates a perspective view of a semiconductor wafer, which may be used for fabricating an N-type, laterally diffused metal oxide semiconductor (LDMOS) transistor having a non-uniformly doped layer in an N-type buried layer, according to aspects of the present disclosure. A wafer 100 may be a semiconductor wafer or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a single material (e.g., silicon (Si), germanium (Ge)) or a compound material, such as gallium arsenide (GaAs), gallium nitride (GaN), or indium phosphide (InP), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, diverse types of electronic devices may be formed in or on the wafer 100.

The wafer 100 has an orientation 102 that indicates the crystalline orientation of the wafer 100. The orientation 102 may be a flat edge of the wafer 100 as shown in FIG. 1 or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and l, which are the Miller indices for a plane (hkl) in the crystal. Each index denotes a plane orthogonal to a direction (h, k, l) on the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to C. For some crystals, negative numbers are used (written as a bar over the index number) and for some crystals, such as gallium nitride, more than three numbers may be employed to describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

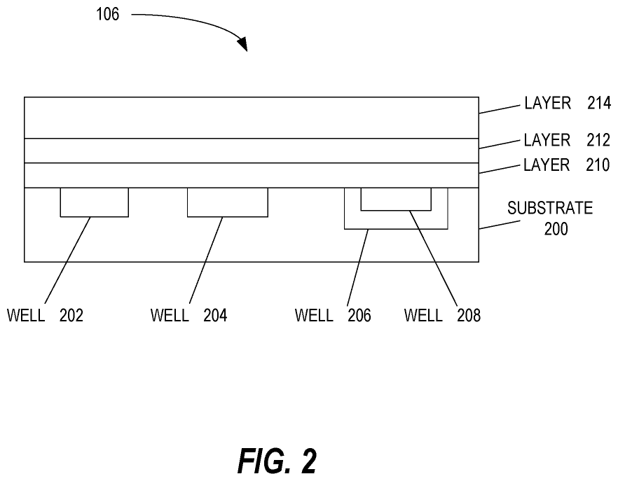

FIG. 2 illustrates a cross-sectional view of the die 106 of FIG. 1, which may be used for fabricating an N-type, laterally diffused metal oxide semiconductor (LDMOS) device having a non-uniformly doped layer in an N-type buried layer, according to aspects of the present disclosure. In the die 106, there may be a substrate 200, which may be a semiconductor material and/or may function as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within the substrate 200 (e.g., a semiconductor substrate), there may be wells 202 and 204 of a field effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT). The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure.

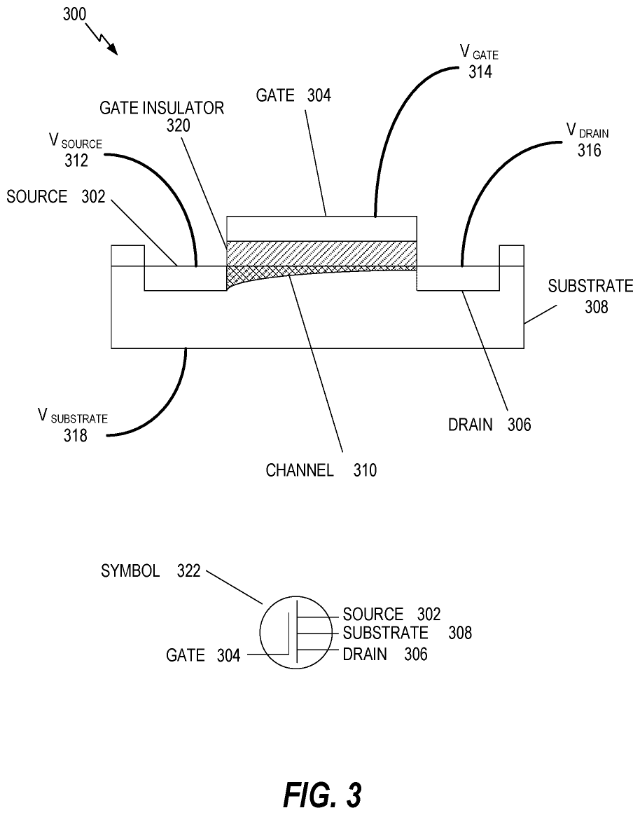

FIG. 3 illustrates a cross-sectional view of a metal oxide semiconductor field effect transistor (MOSFET) device 300. The MOSFET device 300 may have four input terminals. The four inputs are a source 302, a gate 304, a drain 306, and a body. The source 302 and the drain 306 may be fabricated as the wells 202 and 204 in a substrate 308 or may be fabricated as areas above the substrate 308, or as part of other layers on the die 106. Such other structures may be a fin or other structure that protrudes from a surface of the substrate 308. Further, the substrate 308 may be the substrate 200 on the die 106, but the substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314, or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For P-type MOSFETs (using holes as charge carriers in the channel 310), an arrow is applied to the substrate 308 terminal in the symbol 322 pointing toward the gate 304 terminal.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304, as described below.

To interconnect to the MOSFET device 300, or to interconnect to other devices in the die 106 (e.g., semiconductor), interconnect traces or layers are used. These interconnect traces may be in one or more layers (e.g., 210-214), or may be in other layers of the die 106.

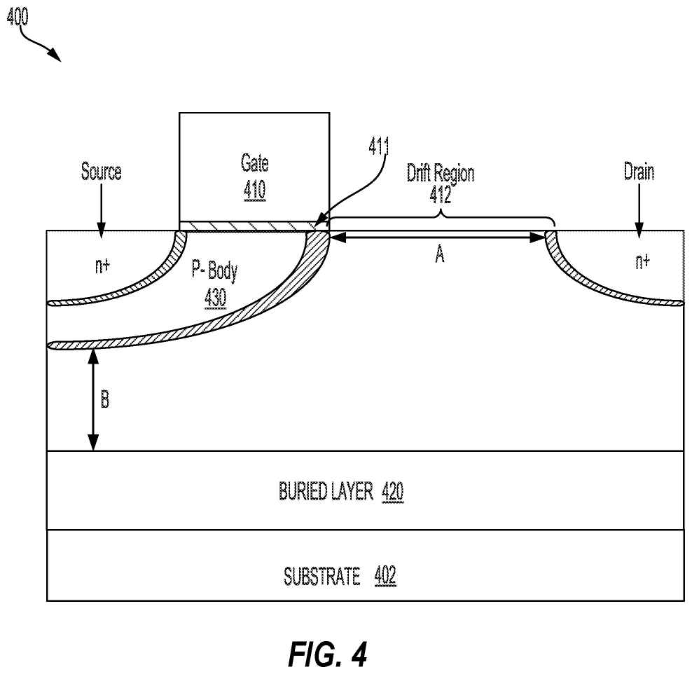

FIG. 4 is a cross-sectional view of an N-type, laterally diffused metal oxide semiconductor (LDMOS) transistor, according to various aspects of the present disclosure. Representatively, an integrated circuit (IC) device includes an active device 400 having a gate 410, a body region 430 (e.g., well), a gate oxide 411 between the body region 430 and the gate 410, a source region, and a drain region formed on a buried layer 420. In this configuration, the active device 400 is an LDMOS transistor, as noted by a drift region 412 between the body region 430 and the drain region. The LDMOS transistor is shown in an N-type field effect transistor (NFET) configuration, although other configurations are possible.

LDMOS transistors represent a type of an asymmetric power metal oxide semiconductor field effect transistor (MOSFET). In operation, an LDMOS channel current is controlled by a vertical electric field induced by the gate and a lateral field that exists between the source and drain. That is, an LDMOS transistor operates based on a lateral surface-effect due to the drift region (e.g., 412) of LDMOS structures. In operation, a breakdown voltage (BV) of a high side, N-channel LDMOS (NLDMOS) transistor (having a body isolated from the substrate) configuration of the active device 400 is determined by distance “A (lateral BV)” and “B (vertical BV).” In practice, the lateral BV dimension A depends on the layout of an IC device, so the lateral BV dimension A is flexible. By contrast, the vertical BV dimension B depends on an epitaxial (EPI) thickness of a buried layer, so the vertical BV dimension B is fixed.

A low voltage (e.g., 30-volt (V)) IC process for fabricating a low voltage NLDMOS transistor specifies a fixed lateral BV dimension A. In order to increase the vertical BV dimension B for a high voltage NLDMOS transistor (e.g., 60 V) with the fixed vertical BV dimension B of the low voltage IC process, various aspects of the present disclosure reduce a doping concentration of the buried layer 420 (e.g., N+ buried layer) with an additional mask layer. As shown in FIG. 4, the buried layer 420 is a part of a base of a parasitic positive-negative-positive (PNP) junction, which is turned on during power transistor switching. In particular, a higher parasitic PNP junction beta can cause a latch up issue or efficiency degradation. Additionally, the higher parasitic PNP junction beta increases the latch up risk and efficiency degradation. Simply replacing the buried layer 420 with a lighter doped buried layer (e.g., ˜50× lower) to increase the vertical BV causes a significant increase (e.g., ˜20 times) of the parasitic PNP junction beta.

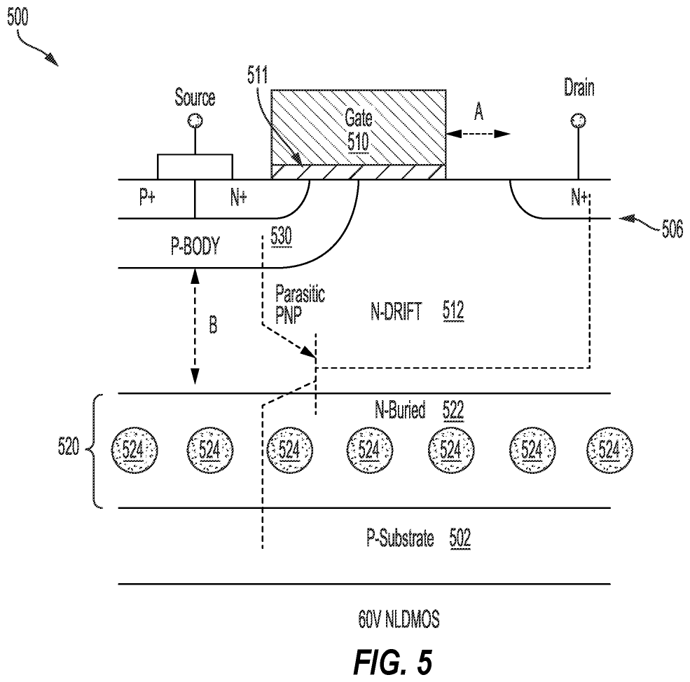

FIG. 5 is a cross-sectional view of an N-type, laterally diffused metal oxide semiconductor (LDMOS) transistor having a non-uniformly doped layer in an N-type buried layer, according to various aspects of the present disclosure. Representatively, an integrated circuit (IC) device includes an active device 500 having a gate 510, a body 530 (e.g., well), a gate oxide 511 between the body 530 and the gate 510, a source region, a drain region formed on a buried layer 520, and a substrate 502 (e.g., P-type). In this configuration, the active device 500 is also an LDMOS transistor, as noted by a drift region 512 between the body 530 and the drain region. The LDMOS transistor is shown in the NFET configuration, although other configurations are possible.

In various aspects of the present disclosure, the buried layer 520 includes a non-uniformly doped layer 524 in an N-type buried layer 522 to provide a high voltage (e.g., 60 V) NLDMOS transistor configuration of the active device 500 (e.g., a first LDMOS transistor). In some aspects of the present disclosure, the non-uniformly doped layer 524 is composed of a diluted N+ buried layer (e.g., ˜3e¹⁴/cm²) inside of the N-type buried layer 522 composed of a lighter doped N− buried layer (e.g. ˜5e¹³/cm²). The diluted N+ buried layer of the non-uniformly doped layer 524 is covered by the lighter doped N− buried layer of the N-type buried layer 522, which avoids a breakdown voltage (BV) degradation. This placement of the non-uniformly doped layer 524 in the N-type buried layer 522, however, significantly reduces (e.g., 5× lower) the parasitic positive-negative-positive (PNP) junction beta.

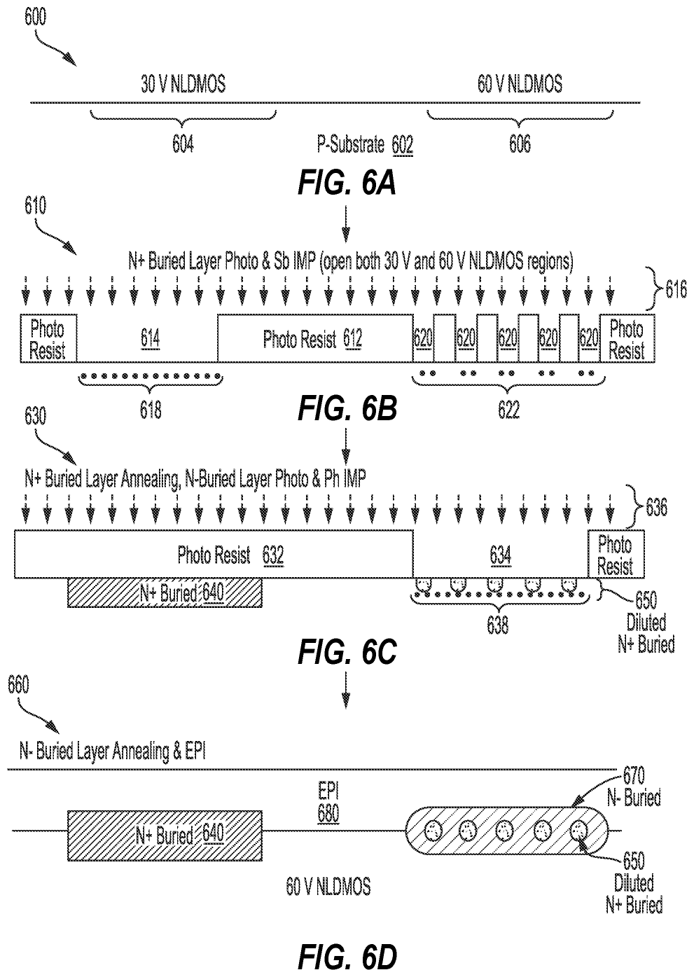

In various aspects of the present disclosure, fabrication of the active device 500 as the high voltage NLDMOS transistor (e.g., a first LDMOS transistor) shown in FIG. 5 using a low voltage integrated circuit (IC) process involves a low power NLDMOS transistor (e.g., a second LDMOS transistor). In order to support fabrication of both the low voltage (e.g., 30 V) and the high voltage (e.g., 60 V), NLDMOS structure fabrication involve providing both an N+ buried layer and an N− buried layer. According to various aspects of the present disclosure, a window size opening is adjusted to vary an implant dose and depth. In these aspects of the present disclosure, a reduced window size produces a lighter doping (e.g., a diluted N+ buried layer) without involving any additional mask, for example, as shown in FIGS. 6A-6D.

FIGS. 6A-6D are schematic diagrams illustrating formation of the N-type, laterally diffused metal oxide semiconductor device (LDMOS) transistor structures, according to various aspects of the present disclosure. According to aspects of the present disclosure, FIGS. 6A-6D illustrate a process of fabricating a higher voltage LDMOS transistor fabricated using a lower voltage integrated circuit (IC) process.

As shown in FIG. 6A, the process of fabricating a higher voltage LDMOS transistor fabricated using a lower voltage IC process begins at step 600 in which a substrate 602 (e.g., P-type) is formed including a first substrate region 604 (e.g., a low voltage NLDMOS structure) and a second substrate region 606 (e.g., a low voltage NLDMOS structure).

A shown in FIG. 6B, the process continues at step 610 by depositing and patterning a first photoresist (PR) layer 612 on the substrate 602 to form a first window opening 614 in the first PR layer 612, exposing the first substrate region 604 and second window openings 620 in the first PR layer 612, exposing the second substrate region 606. The process also includes implanting a first dopant 616 (e.g., an antimony (Sb) or arsenic (As) implant (IMP)) in the first substrate region 604 through the first window opening 614 to form a first implant region 618. The process also includes implanting the first dopant 616 in the second substrate region 606 through the second window openings 620 in the first PR layer 612 to form a second implant region 622.

As shown in FIG. 6C, the process continues at step 630 by annealing the substrate 602 to form a doped N+ buried layer 640 in the first substrate region 604 and a diluted (e.g., lightly doped) N+ buried layer 650 in the second substrate region 606. The process also includes depositing and patterning a second PR layer 632 on the substrate 602 to form a window opening 634 exposing the second substrate region 606, including the diluted N+ buried layer 650. The process further includes implanting a second dopant 636 (e.g., a phosphorus (Ph) implant (IMP)) in the diluted N+ buried layer 650 in the second substrate region through the window opening 634 in the second PR layer 632 to form a third implant region 638.

As shown in FIG. 6D, the process continues at step 660 by annealing the substrate 602 and the third implant region 638 to form a non-uniformly doped N− buried layer 670 in the second substrate region 606, including the diluted N+ buried layer 650. The annealing is followed by epitaxial growth of an epitaxial (EPI) layer 680. The process shown in FIGS. 6A-6D adds the diluted N+ buried layer 650 without an additional mask enabling formation of a high voltage (e.g., 60 V) NLDMOS transistor configuration of the active device 500 (see FIG. 5), having a significantly reduced (e.g., 5× lower) positive-negative-positive (PNP) junction beta. In operation, a parasitic PNP junction current causes a latch-up issue, resulting in a significant spacing (e.g., >50 microns) between a power transistor and adjacent devices for a conventional high power (e.g., 60 V) NLDMOS structure.

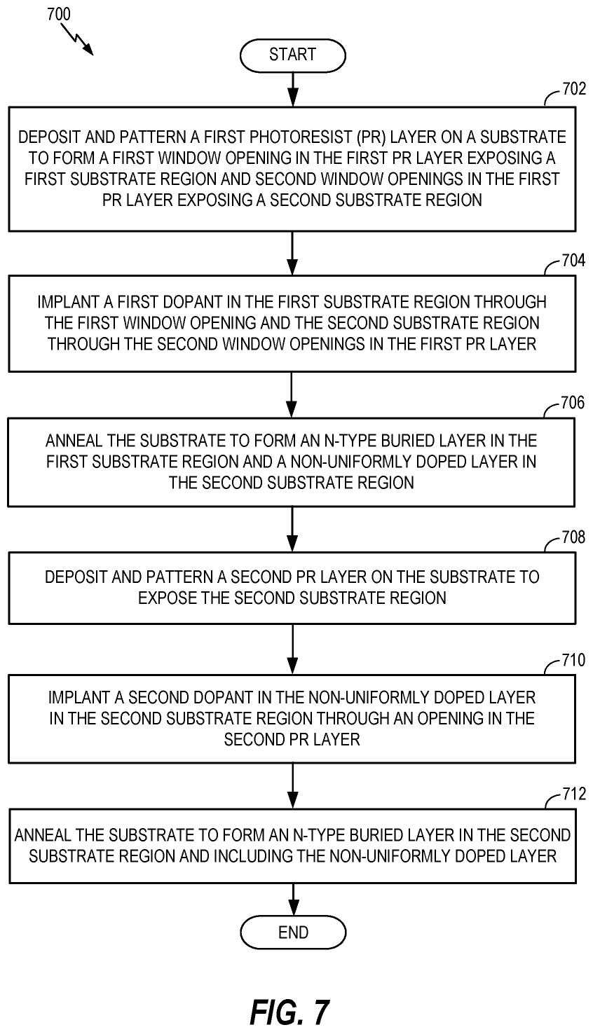

In various aspects of the present disclosure, a high voltage (e.g., 60 V) NLDMOS structure exhibits a significantly lower (e.g., 5× lower) parasitic PNP junction beta. As a result, a spacing between the power transistor and adjacent device structure is significantly reduced (e.g., ˜10 microns). Additionally, the high voltage (e.g., 60 V) NLDMOS structure supports an overall chip size reduction (e.g., 2-3%). Furthermore, by reducing the parasitic PNP junction current, the high voltage (e.g., 60 V) NLDMOS structure avoids unnecessary power consumption, which may cause an efficiency degradation. In particular, the high voltage (e.g., 60 V) NLDMOS structure significantly reduces power consumption (e.g., by ˜5×). A process of fabricating an LDMOS structure having a non-uniformly doped layer in an N-type buried layer may be performed, for example, as shown in FIG. 7.

FIG. 7 is a process flow diagram illustrating a method 700 for transistor integration, according to aspects of the present disclosure. The method 700 begins at block 702, in which a first photoresist (PR) layer is deposited and patterned on a substrate to form a first window opening in the first PR layer exposing a first substrate region and second window openings in the first PR layer exposing a second substrate region. For example, as shown in FIG. 6B, at step 610 by depositing and patterning a first photoresist (PR) layer 612 on the substrate 602 to form a first window opening 614 in the first PR layer 612, exposing the first substrate region 604 and second window openings 620 in the first PR layer 612, exposing the second substrate region 606.

At block 704, a first dopant is implanted in the first substrate region through the first window opening and the second substrate region through the second window openings in the first PR layer. For example, as shown in FIG. 6B, the process also includes implanting a first dopant 616 (e.g., an antimony (Sb) or arsenic (As) implant (IMP)) in the first substrate region 604 through the first window opening 614 to form a first implant region 618. The process also includes implanting the first dopant 616 in the second substrate region 606 through the second window openings 620 in the first PR layer 612 to form a second implant region 622.

At block 706, the substrate is annealed to form an N-type buried layer in the first substrate region and a non-uniformly doped layer in the second substrate region. For example, FIG. 6C, the process continues at step 630 by annealing the substrate 602 to form a doped N+ buried layer 640 in the first substrate region 604 and a diluted (e.g., lightly doped) N+ buried layer 650 in the second substrate region 606.

At block 708, a second PR layer is deposited and patterned on the substrate to expose the second substrate region. For example, as shown in FIG. 6C, the process also includes depositing and patterning a second PR layer 632 on the substrate 602 to form a window opening 634 exposing the second substrate region 606, including the diluted N+ buried layer 650.

At block 710, a second dopant is implanted in the non-uniformly doped layer in the second substrate region through an opening in the second PR layer. For example, as shown in FIG. 6C, the process further includes implanting a second dopant 636 (e.g., a phosphorus (Ph) implant (IMP)) in the diluted N+ buried layer 650 in the second substrate region through the window opening 634 in the second PR layer 632 to form a third implant region 638.

At block 712, the substrate is annealed to form an N-type buried layer in the second substrate region and including the non-uniformly doped layer. For example, as shown in FIG. 6D, the process continues at step 660 by annealing the substrate 602 and the third implant region 638 to form a non-uniformly doped N− buried layer 670 in the second substrate region 606, including the diluted N+ buried layer 650.

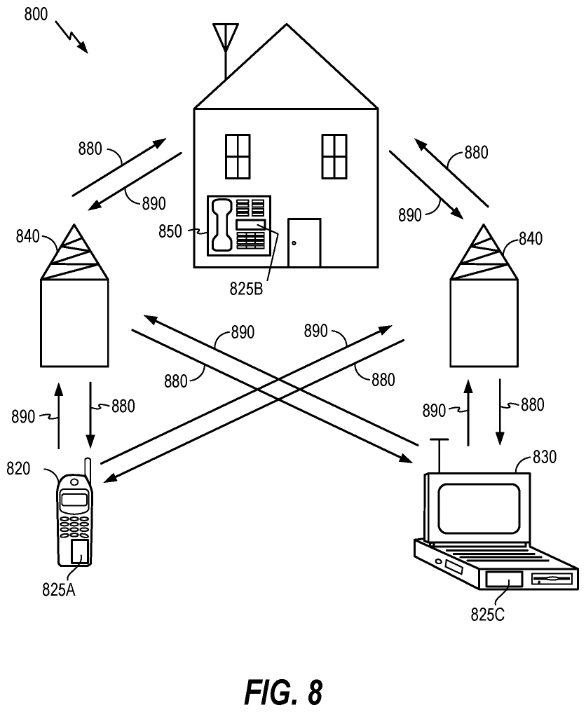

FIG. 8 is a block diagram showing an exemplary wireless communications system 800 in which an aspect of the disclosure may be advantageously employed. For purposes of illustration, FIG. 8 shows three remote units 820, 830, and 850, and two base stations 840. It will be recognized that wireless communications systems may have many more remote units and base stations. Remote units 820, 830, and 850 include IC devices 825A, 825C, and 825B that include the disclosed LDMOS transistor. It will be recognized that other devices may also include the disclosed LDMOS transistor, such as the base stations, switching devices, and network equipment. FIG. 8 shows forward link signals 880 from the base station 840 to the remote units 820, 830, and 850, and reverse link signals 890 from the remote units 820, 830, and 850 to base station 840.

In FIG. 8, remote unit 820 is shown as a mobile telephone, remote unit 830 is shown as a portable computer, and remote unit 850 is shown as a fixed location remote unit in a wireless local loop system. For example, the remote units may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as meter reading equipment, or other devices that store or retrieve data or computer instructions, or combinations thereof. Although FIG. 8 illustrates remote units according to the aspects of the disclosure, the disclosure is not limited to these exemplary illustrated units. Aspects of the disclosure may be suitably employed in many devices, which include the disclosed LDMOS transistor.

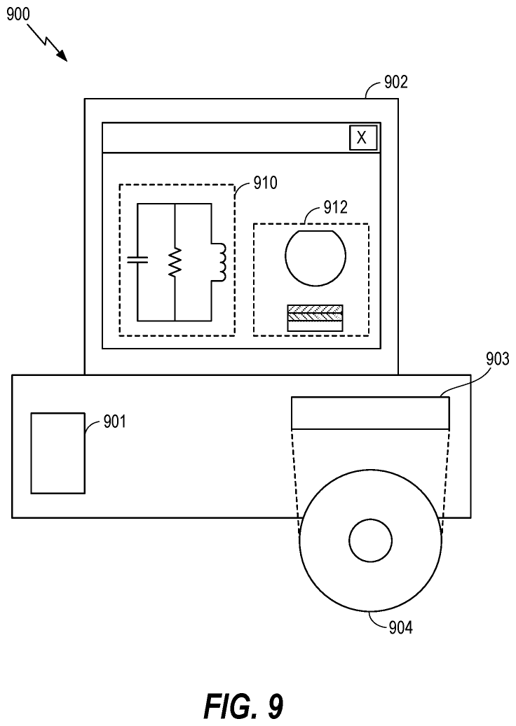

FIG. 9 is a block diagram illustrating a design workstation used for circuit, layout, and logic design of an IC structure, such as the FinFET disclosed above. A design workstation 900 includes a hard disk 901 containing operating system software, support files, and design software such as Cadence or OrCAD. The design workstation 900 also includes a display 902 to facilitate design of a circuit 910 or a LDMOS structure 912 including a GAA FET. A storage medium 904 is provided for tangibly storing the design of the circuit 910 or the LDMOS structure 912. The design of the circuit 910 or the LDMOS structure 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904. For example,

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit 910 or the LDMOS structure 912 by decreasing the number of processes for designing semiconductor wafers.

Implementation examples are described in the following numbered clauses:
1. An integrated circuit (IC) device, comprising:
a P-type substrate;
an N-type buried layer on the substrate and including a non-uniformly doped layer in the N-type buried layer, the non-uniformly doped layer being proximate a first substrate region; and
a first laterally diffused metal oxide semiconductor (LDMOS) transistor on the first substrate region.
2. The IC device of clause 1, in which the N-type buried layer comprises a lightly doped N− buried layer.
3. The IC device of clause 2, in which the non-uniformly doped buried layer comprises a diluted N+ buried layer in the lightly doped N− buried layer.
4. The IC device of any of clauses 1-3, in which the first LDMOS transistor comprises an N-channel LDMOS (NLDMOS) transistor.
5. The IC device of clause 4, in which the NLDMOS transistor comprises a source region, a drain region, a gate, a body region, and a drift region between the drain region and the body region.
6. The IC device of any of clauses 1-5, further comprising a second LDMOS transistor on the N-type buried layer on a second substrate region outside the first substrate region.
7. The IC device of clause 6, in which the second LDMOS transistor comprises an N-channel LDMOS (NLDMOS) transistor.
8. The IC device of clause 6, in which the second LDMOS transistor comprises an N+ buried layer.
9. The IC device of clause 6, in which the second LDMOS transistor comprises a low voltage NLDMOS transistor.
10. The IC device of any of clauses 1-9, in which the first LDMOS transistor comprises a high voltage NLDMOS transistor.
11. A method for transistor integration, comprising:
depositing and patterning a first photoresist (PR) layer on a substrate to form a first window opening in the first PR layer exposing a first substrate region and second window openings in the first PR layer exposing a second substrate region; implanting a first dopant in the first substrate region through the first window opening and the second substrate region through the second window openings in the first PR layer;
annealing the substrate to form an N-type buried layer in the first substrate region and a non-uniformly doped layer in the second substrate region;
depositing and patterning a second PR layer on the substrate to expose the second substrate region;
implanting a second dopant in the non-uniformly doped layer in the second substrate region through an opening in the second PR layer; and
annealing the substrate to form an N-type buried layer in the second substrate region and including the non-uniformly doped layer.
12. The method of clause 11, in which a size of the second plurality of window openings is less than a size of the first window opening to form the diluted N+ buried layer.
13. The method of clause 11 or 12, in which the N-type buried layer in the second substrate region comprises a lightly doped N− buried layer.
14. The method of clause 13, in which the non-uniformly doped buried layer comprises a diluted N+ buried layer in the lightly doped N− buried layer.
15. The method of any of clauses 11-14, further comprising:
forming a first laterally diffused metal oxide semiconductor (LDMOS) transistor on the first substrate region; and
forming a second laterally diffused metal oxide semiconductor (LDMOS) transistor on the second substrate region.
16. The method of clause 15, in which the first LDMOS transistor comprises a first N-channel LDMOS (NLDMOS) transistor.
17. The method of clause 15, in which the second LDMOS transistor comprises a second N-channel LDMOS (NLDMOS) transistor.
18. The method of clause 15, in which the first LDMOS transistor comprises a low voltage N-channel LDMOS (NLDMOS) transistor.
19. The method of clause 15, in which the second LDMOS transistor comprises a high voltage N-channel LDMOS (NLDMOS) transistor.
20. The method of any of clauses 11-19, further comprising growing an epitaxial (EPI) layer on the first substrate region and the second substrate region.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general-purpose or special-purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit (IC) device, comprising:
a P-type substrate;
an N-type buried layer on the substrate and including a non-uniformly doped layer in the N-type buried layer, the non-uniformly doped layer being proximate a first substrate region; and
a first laterally diffused metal oxide semiconductor (LDMOS) transistor on the first substrate region.

2. The IC device of claim 1, in which the N-type buried layer comprises a lightly doped N− buried layer.

3. The IC device of claim 2, in which the non-uniformly doped buried layer comprises a diluted N+ buried layer in the lightly doped N− buried layer.

4. The IC device of claim 1, in which the first LDMOS transistor comprises an N-channel LDMOS (NLDMOS) transistor.

5. The IC device of claim 4, in which the NLDMOS transistor comprises a source region, a drain region, a gate, a body region, and a drift region between the drain region and the body region.

6. The IC device of claim 1, further comprising a second LDMOS transistor on the N-type buried layer on a second substrate region outside the first substrate region.

7. The IC device of claim 6, in which the second LDMOS transistor comprises an N-channel LDMOS (NLDMOS) transistor.

8. The IC device of claim 6, in which the second LDMOS transistor comprises an N+ buried layer.

9. The IC device of claim 6, in which the second LDMOS transistor comprises a low voltage NLDMOS transistor.

10. The IC device of claim 1, in which the first LDMOS transistor comprises a high voltage NLDMOS transistor.

11. A method for transistor integration, comprising:
depositing and patterning a first photoresist (PR) layer on a substrate to form a first window opening in the first PR layer exposing a first substrate region and second window openings in the first PR layer exposing a second substrate region;
implanting a first dopant in the first substrate region through the first window opening and the second substrate region through the second window openings in the first PR layer;
annealing the substrate to form an N-type buried layer in the first substrate region and a non-uniformly doped layer in the second substrate region;
depositing and patterning a second PR layer on the substrate to expose the second substrate region;
implanting a second dopant in the non-uniformly doped layer in the second substrate region through an opening in the second PR layer; and
annealing the substrate to form an N-type buried layer in the second substrate region and including the non-uniformly doped layer.

12. The method of claim 11, in which a size of the second plurality of window openings is less than a size of the first window opening to form the diluted N+ buried layer.

13. The method of claim 11, in which the N-type buried layer in the second substrate region comprises a lightly doped N− buried layer.

14. The method of claim 13, in which the non-uniformly doped buried layer comprises a diluted N+ buried layer in the lightly doped N− buried layer.

15. The method of claim 11, further comprising:
forming a first laterally diffused metal oxide semiconductor (LDMOS) transistor on the first substrate region; and
forming a second laterally diffused metal oxide semiconductor (LDMOS) transistor on the second substrate region.

16. The method of claim 15, in which the first LDMOS transistor comprises a first N-channel LDMOS (NLDMOS) transistor.

17. The method of claim 15, in which the second LDMOS transistor comprises a second N-channel LDMOS (NLDMOS) transistor.

18. The method of claim 15, in which the first LDMOS transistor comprises a low voltage N-channel LDMOS (NLDMOS) transistor.

19. The method of claim 15, in which the second LDMOS transistor comprises a high voltage N-channel LDMOS (NLDMOS) transistor.

20. The method of claim 11, further comprising growing an epitaxial (EPI) layer on the first substrate region and the second substrate region.
